(19) United States
(12) Patent Application Publication
(10) Pub. No.: US 2026/0238187 A1
(43) Pub. Date: Aug. 13, 2026

(54) PIEZOELECTRIC RESONATOR PLATE AND PIEZOELECTRIC RESONATOR DEVICE

(71) Applicant: DAISHINKU CORPORATION, Kakogawa-shi, Hyogo (JP)

(72) Inventors: Kenta AWA, Kakogawa-shi (JP); Hiroki FUJIWARA, Kakogawa-shi (JP); Hiroaki YAMASHITA, Kakogawa-shi (JP)

(73) Assignee: DAISHINKU CORPORATION, Kakogawa-shi, Hyogo (JP)

(21) Appl. No.: 19/156,910

(22) PCT Filed: Feb. 21, 2024
(86) PCT No.: PCT/JP2024/006377

§ 371 Date: Aug. 15, 2025

(30) Foreign Application Priority Data
Mar. 3, 2023 (JP) 2023-032554

(51) Int. Cl. H03H 9/19

(52) U.S. Cl. CPC H03H 9/19

(57) ABSTRACT

A crystal resonator plate 10 includes: a vibrating part 11; an external frame part 12; a support part 13; and a cutout part 10a between the vibrating part 11 and the external frame part 12. An electrode formed on a first main surface is connected to an electrode formed on a second main surface via an internal wiring 17 formed on an inner wall surface of the external frame part 12. In the cutout part 10a, when a first area A1 represents an area sandwiched between the inner wall surface of the external frame part 12 and an outer wall surface of the vibrating part 11, and when, in a remaining space of the cutout part 10a except the first area A1, a second area A2 represents an area sandwiched between the inner wall surface of the external frame part 12 and an outer wall surface of the support part 13 and a third area A3 represents an area sandwiched between two parts of the inner wall surface of the external frame part 12, the internal wiring 17 is formed on the inner wall surface of the external frame part 12, at a position facing at least one of the second area A2 and the third area A3.

### TECHNICAL FIELD

The present invention relates to a piezoelectric resonator plate and a piezoelectric resonator device including the piezoelectric resonator plate.

### BACKGROUND ART

Recently, in various electronic devices, the operating frequencies have increased and the package sizes (especially the heights) have been decreased. According to such an increase in operating frequency and a reduction in package size, there is also a need for crystal resonator devices (such as a crystal resonator and a crystal oscillator) to be adaptable to the increase in operating frequency and the reduction in package size.

Crystal resonator devices having a so-called sandwich structure are known as the crystal resonator devices suitable for reduction in size and height. In the crystal resonator device having a sandwich structure, the housing is formed by a package having a substantially rectangular parallelepiped shape. The package is constituted of: a first sealing member and a second sealing member both made of, for example, glass or crystal; and a crystal resonator plate on respective main surfaces thereof excitation electrodes are formed. The first sealing member and the second sealing member are laminated and bonded via the crystal resonator plate. Thus, a vibrating part of the crystal resonator plate that is disposed in the package (in the internal space) is hermetically sealed by the first sealing member and the second sealing member (see, for example, Patent Document 1).

### PRIOR ART DOCUMENT

### Patent document

Patent Document 1: JP 2010-252051 A

### SUMMARY OF THE INVENTION

### Problem to Be Solved by the Invention

In the piezoelectric resonator plate as described above, when an electrode formed on one main surface is connected to an electrode formed on the other main surface using, for example, a through hole formed in an external frame part, it is necessary to ensure a space for forming the through hole. As a result, it becomes difficult for the piezoelectric resonator plate to be adaptable to size reduction. Also, when the distance between the vibrating part and the external frame part becomes small according to the size reduction, the vibrating part may come into contact with wirings formed on the external frame part, which may result in disconnection of wiring or the like.

The present invention was made in consideration of the above circumstances, an object of which is to provide a piezoelectric resonator plate adaptable to size reduction and capable of maintaining stable electrical characteristics, and accordingly to provide a piezoelectric resonator device including the piezoelectric resonator plate.

### Means for Solving the Problem

In order to solve the above problems, a piezoelectric resonator plate having a rectangular shape of the present invention includes: a first excitation electrode formed on a first main surface of a substrate; and a second excitation electrode formed on a second main surface of the substrate, which makes a pair with the first excitation electrode. The piezoelectric resonator plate further includes: a vibrating part having a rectangular shape; an external frame part surrounding an outer periphery of the vibrating part; a support part connecting a part of the vibrating part to a part of the external frame part; and a cutout part formed by cutting out the substrate such that the cutout part is interposed between the vibrating part and the external frame part. An electrode formed on the first main surface of the substrate is electrically connected to an electrode formed on the second main surface of the substrate via an internal wiring formed on an inner wall surface of the external frame part. In a space of the cutout part, when a first area represents an area sandwiched between the inner wall surface of the external frame part and an outer wall surface of the vibrating part, and when, in a remaining space of the cutout part except the first area, a second area represents an area sandwiched between the inner wall surface of the external frame part and an outer wall surface of the support part and furthermore a third area represents an area sandwiched between two parts of the inner wall surface of the external frame part, the internal wiring is formed on the inner wall surface of the external frame part, at a position facing at least one of the second area and the third area. In this case, examples of the electrodes formed on the first main surface and the second main surface of the substrate include: an electrode of an annular sealing part (seal path) for hermetically sealing the vibrating part of the piezoelectric resonator plate; a wiring electrode for earth-connecting; each lead-out electrode drawn out from the first and the second excitation electrodes; and a wiring electrode connected to an IC mounted on a piezoelectric oscillator.

With the above-described configuration, it is possible to reduce the size of the piezoelectric resonator plate while maintaining stability of the electrical characteristics. Specifically, since the electrode formed on the first main surface is connected to the electrode formed on the second main surface via the internal wiring, there is no need to form the through holes or the like in the external frame part. Thus, it is possible to reduce the size of the piezoelectric resonator plate while maintaining the effective area of the vibrating part. Also, a part of the inner wall surface of the external frame part, which faces (makes contact with) the second or the third area, has a large width of cutout compared to the adjacent part of the inner wall surface of the external frame part, which faces (makes contact with) the first area. Thus, it is possible to ensure a space within the opposite wall surface. In this way, it is possible to prevent the vibrating part from making contact with the inner wiring, which reduces possible disconnection and the like. Furthermore, it is possible to easily and reliably form the internal wiring on the inner wall surface of the external frame part. It is also possible to reliably remove resist on the inner wall surface of the external frame part and on the outer wall surface of the vibrating part in the photolithography process for forming the internal wiring on the inner wall surface of the external frame part, which leads to reliable forming of the internal wiring on the inner wall surface of the external frame part. Therefore, since the electrode formed on the first main surface can be electrically stably and reliably conducted to the electrode formed on the second main surface, it is possible to prevent degradation of electrical characteristics of the piezoelectric resonator plate and to reduce occurrence of defective products.

In the above-described piezoelectric resonator plate, it is preferable that: the inner wall surface of the external frame part is formed annularly so as to have a rectangular shape in plan view; a notch part is formed at a corner part of the inner wall surface in plan view so as to cut into the external frame part; and the internal wiring is formed on an inner wall surface of the notch part.

With the piezoelectric resonator plate having the above-described configuration, it is possible to prevent disconnection of the internal wiring by forming the inner wall surface of the notch part as the inclined surface. Also, since the notch part is formed so as to cut into the external frame part, it is possible to ensure the effective area of the vibrating part, which leads to the piezoelectric resonator plate having a reduced size and stable electrical characteristics.

A piezoelectric resonator device of the present invention includes the piezoelectric resonator plate as described above. The piezoelectric resonator device further includes: a first sealing member covering the first excitation electrode of the piezoelectric resonator plate; and a second sealing member covering the second excitation electrode of the piezoelectric resonator plate. An internal space is formed by bonding the first sealing member to the piezoelectric resonator plate and furthermore by bonding the second sealing member to the piezoelectric resonator plate. The internal space hermetically seals the vibrating part including the first excitation electrode and the second excitation electrode of the piezoelectric resonator plate.

With the piezoelectric resonator device having the above-described configuration, it is possible to obtain the same functions and effects as those explained above on the piezoelectric resonator plate. Furthermore, since the internal wiring is not exposed to the outer surface of the package of the piezoelectric resonator device, it is possible to prevent disconnection or scraping of the internal wiring caused by contact or the like during assembly or transport.

In the above-described piezoelectric resonator device, it is preferable that a grounding electrode formed on one main surface of both main surfaces of the first sealing member is electrically connected to an external electrode terminal formed on a main surface, which does not face the internal space, of the second sealing member via the internal wiring. With this configuration, it is possible to reliably connect the grounding electrode to the external electrode terminal via the internal wiring, which improves shieldability by the grounding electrode.

In the above-described piezoelectric resonator device, it is preferable that annular-shaped sealing parts are respectively provided between the first sealing member and the piezoelectric resonator plate, and between the second sealing member and the piezoelectric resonator plate, so as to hermetically seal the vibrating part of the piezoelectric resonator plate. Also, it is preferable that the respective annular-shaped sealing parts are electrically connected to the internal wiring. With this configuration, it is possible to reliably connect the sealing parts to each other via the internal wiring.

In the above-described piezoelectric resonator device, it is preferable that the piezoelectric resonator plate includes only one support part and that the one support part extends from a corner part of the vibrating part toward the external frame part. With this configuration, it is possible to ensure multiple second areas and multiple third areas in the cutout part. Thus, the stability of conduction by the internal wiring can be improved, and furthermore the main vibration of the piezoelectric resonator plate is not likely to be reduced.

In the above-described piezoelectric resonator device, it is preferable that the piezoelectric resonator plate is made of an AT-cut crystal resonator plate, and that the internal wiring is formed on the inner wall surface of the external frame part along the Z′ axis direction of the AT-cut crystal plate. During the wet etching process for forming the cutout part, an inclined surface often including an acute angle is formed on the inner wall surface of the external frame part along the X axis direction of the AT-cut crystal, which may result in disconnection or the like at the time of forming the internal wiring. However, such a part having an acute angle is not likely to appear on the inner wall surface of the external frame part along the Z′ axis direction of the AT-cut crystal. Therefore, it is possible to easily form the internal wiring while reducing the risk of disconnection or the like.

### Effects of the Invention

The piezoelectric resonator plate and the piezoelectric resonator device of the present invention are adaptable to size reduction and furthermore capable of maintaining stable electrical characteristics.

### BRIEF DESCRIPTION OF THE DRAWINGS

FIG. 1 is a schematic configuration diagram schematically illustrating a configuration of a crystal resonator according to an embodiment.

FIG. 2 is a schematic plan view illustrating a first main surface of a first sealing member of the crystal resonator.

FIG. 3 is a schematic plan view illustrating a second main surface of the first sealing member of the crystal resonator.

FIG. 4 is a schematic plan view illustrating a first main surface of a crystal resonator plate according to the embodiment.

FIG. 5 is a schematic plan view illustrating a second main surface of the crystal resonator plate according to the embodiment.

FIG. 6 is a schematic plan view illustrating a first main surface of a second sealing member of the crystal resonator.

FIG. 7 is a schematic plan view illustrating a second main surface of the second sealing member of the crystal resonator.

FIG. 8 is a schematic plan view illustrating the crystal resonator plate according to another embodiment 1, which corresponds to FIG. 4.

FIG. 9 is a schematic plan view illustrating the first sealing member according to another embodiment 2, which corresponds to FIG. 3.

FIG. 10 is a schematic plan view illustrating the crystal resonator plate according to another embodiment 3, which corresponds to FIG. 4.

FIG. 11 is a schematic plan view illustrating the crystal resonator plate according to the other embodiment 3, which corresponds to FIG. 5.

### MODES FOR CARRYING OUT THE INVENTION

Hereinafter, an embodiment of the present invention will be described in detail with reference to the drawings. In the following embodiment, a piezoelectric resonator device to which the present invention is applied is a crystal resonator.

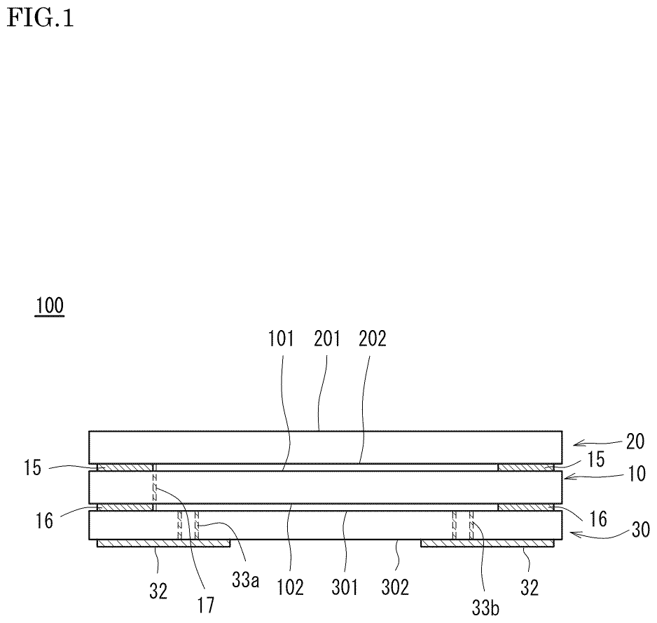

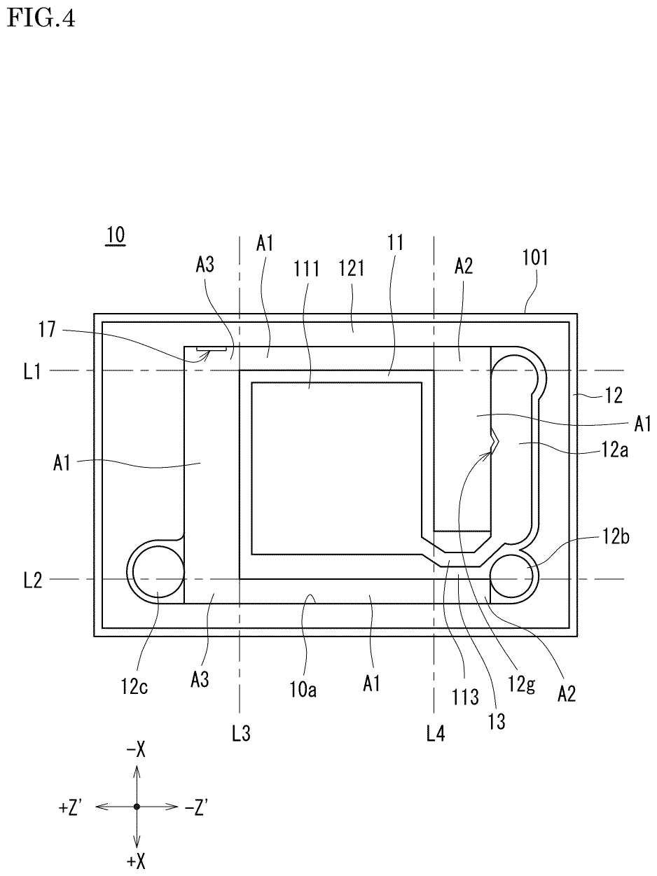

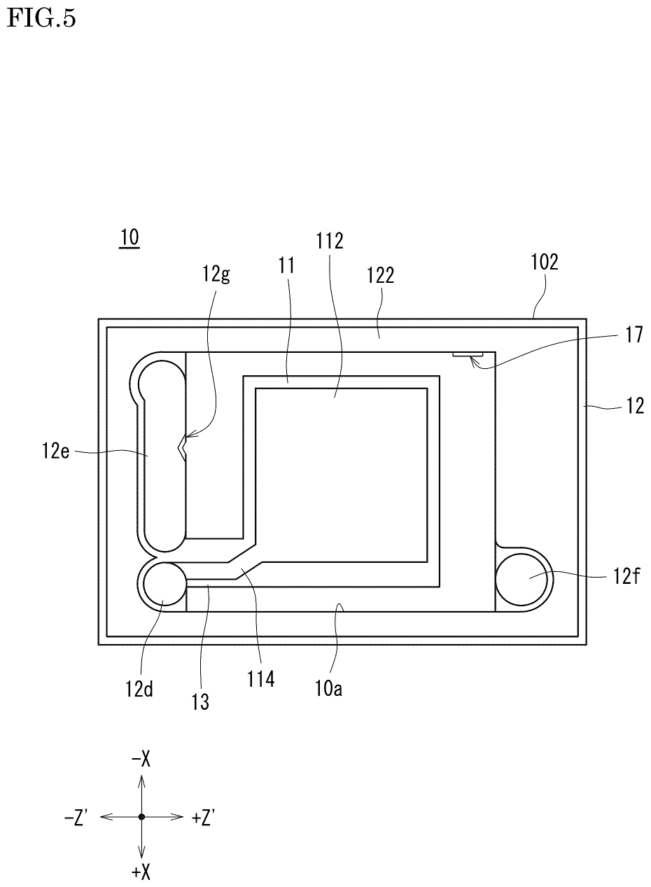

First, the basic configuration of a crystal resonator 100 according to this embodiment is described. As shown in FIG. 1, the crystal resonator 100 includes: a crystal resonator plate (piezoelectric resonator plate) 10; a first sealing member 20; and a second sealing member 30. In this crystal resonator 100, the crystal resonator plate 10 is bonded to the first sealing member 20, and furthermore the crystal resonator plate 10 is bonded to the second sealing member 30. Thus, a package having a sandwich structure is formed so as to have a substantially rectangular parallelepiped shape. That is, in the crystal resonator 100, the first sealing member 20 and the second sealing member 30 are bonded to respective main surfaces of the crystal resonator plate 10, thus an internal space (cavity) of the package is formed. In this internal space, a vibrating part 11 (see FIGS. 4 and 5) is hermetically sealed.

The crystal resonator 100 according to this embodiment has, for example, a package size of 1.0×0.8 mm, which is reduced in size and height. The crystal resonator 100 is electrically connected to an external circuit board (not shown) provided outside via solder.

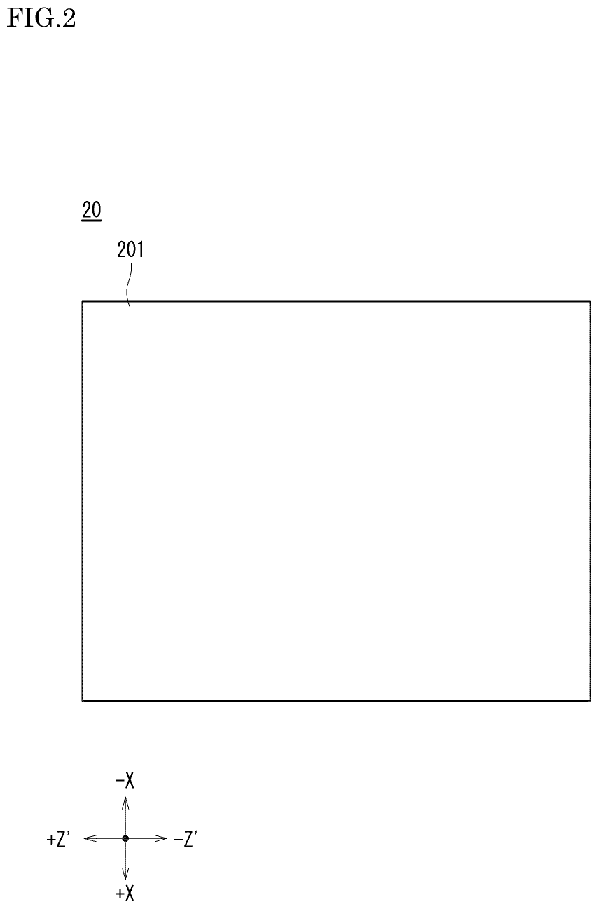

Next, the respective components of the above-described crystal resonator 100 (i.e. the crystal resonator plate 10, the first sealing member 20 and the second sealing member 30) are described with reference to FIGS. 1 to 7. Here, each of the components is described as a single body without being bonded. FIGS. 2 to 7 merely show respective configuration examples of the crystal resonator plate 10, the first sealing member 20 and the second sealing member 30, and thus the present invention is not limited thereto.

The crystal resonator plate 10 is a piezoelectric substrate made of crystal as shown in FIGS. 4 and 5. Each main surface (i.e. a first main surface 101 and a second main surface 102) is formed as a smooth flat surface (mirror-finished). In this embodiment, an AT-cut crystal plate that causes thickness shear vibration is used as the crystal resonator plate 10. In the crystal resonator plate 10 shown in FIGS. 4 and 5, each main surface 101 and 102 of the crystal resonator plate 10 is an XZ′ plane. On this XZ′ plane, the direction parallel to the lateral direction (short side direction) of the crystal resonator plate 10 is the X axis direction, and the direction parallel to the longitudinal direction (long side direction) of the crystal resonator plate 10 is the Z′ axis direction. The AT-cut method is a processing method in which a crystal plate is cut out of synthetic quartz crystal at an angle tilted by 35° 15′ about the X axis from the Z axis, out of the three crystal axes (i.e. an electrical axis (X axis), a mechanical axis (Y axis) and an optical axis (Z axis)) of the synthetic quartz crystal. The X axis of the AT-cut crystal plate equals the crystal axis of the crystal. The Y′ axis and the Z′ axis equal the respective axes that tilt by approximately 35° 15′ from the Y axis and the Z axis out of the crystal axes of the crystal (this cutting angle may be changed to a certain extent within the range in which the frequency temperature characteristics of the AT-cut crystal resonator plate can be adjusted). The Y′ axis direction and the Z′ axis direction correspond to the directions in which the AT-cut crystal plate is cut out.

A pair of excitation electrodes (i.e. a first excitation electrode 111 and a second excitation electrode 112) is formed, respectively, on the main surfaces 101 and 102 of the crystal resonator plate 10. The crystal resonator plate 10 includes: the vibrating part 11 formed so as to have a substantially rectangular shape; an external frame part 12 surrounding the outer periphery of the vibrating part 11; and a support part 13 that supports the vibrating part 11 by connecting the vibrating part 11 to the external frame part 12. That is, the crystal resonator plate 10 has a configuration in which the vibrating part 11, the external frame part 12 and the support part 13 are integrally formed. The support part 13 extends (protrudes) from only one corner part positioned in the +X direction and in the −Z′ direction of the vibrating part 11 to the external frame part 12 in the −Z′ direction. Also, a cutout part 10a is provided between the vibrating part 11 and the external frame part 12 by cutting out the crystal resonator plate 10. In this embodiment, the crystal resonator plate 10 has only one support part 13 to connect the vibrating part 11 to the external frame part 12. The cutout part 10a is continuously formed so as to surround the outer periphery of the vibrating part 11. In this embodiment, neither through hole nor castellation is formed in the external frame part 12 of the crystal resonator plate 10. Also, the crystal resonator plate 10 has no penetrating part other than the cutout part 10a.

The first excitation electrode 111 is provided on the first main surface 101 side of the vibrating part 11 while the second excitation electrode 112 is provided on the second main surface 102 side of the vibrating part 11. The first excitation electrode 111 and the second excitation electrode 112 are respectively connected to lead-out wirings (lead-out electrodes) so that these excitation electrodes are connected to external electrode terminals. A first lead-out wiring 113 is drawn out from the first excitation electrode 111 and connected to a connection bonding pattern 12a formed on the first main surface 101 of the external frame part 12 via the support part 13. Furthermore, the connection bonding pattern 12a is connected to a connection bonding pattern 12e formed on the second main surface 102 of the external frame part 12 via an internal wiring 12g formed on an inner wall surface of the external frame part 12. The internal wiring 12g is provided on the inner wall surface along the X axis direction and on the −Z′ direction side, out of the inner wall surfaces of the external frame part 12. In this case, the internal wiring 12g is formed as a recess having a V shape in plan view, which is provided in the inner wall surface of the external frame part 12. In this way, by forming the V-shaped recess in the inner wall surface of the external frame part 12, the internal wiring 12g can be formed in a state in which it is along the direction other than the X axis direction of the At-cut crystal. Thus, even when an inclined surface is formed in the wet etching process, there also be a part with an angle other than the acute angle. Therefore, it is possible to reduce the risk of disconnection and the like of the wiring. A second lead-out wiring 114 is drawn out from the second excitation electrode 112 and connected to a connection bonding pattern 12d formed on the second main surface 102 of the external frame part 12 via the support part 13.

Resonator-plate-side sealing parts to bond the crystal resonator plate 10 respectively to the first sealing member 20 and the second sealing member 30 are provided on the respective main surfaces (i.e. the first main surface 101 and the second main surface 102) of the crystal resonator plate 10. As the resonator-plate-side sealing part on the first main surface 101, a resonator-plate-side first bonding pattern 121 is formed. As the resonator-plate-side sealing part on the second main surface 102, a resonator-plate-side second bonding pattern 122 is formed. The resonator-plate-side first bonding pattern 121 and the resonator-plate-side second bonding pattern 122 are each formed on the external frame part 12 so as to have an annular shape in plan view. The outer peripheral edge of the resonator-plate-side first bonding pattern 121 is disposed so as to be adjacent to the outer peripheral edge of the first main surface 101 of the crystal resonator plate 10 (external frame part 12). The outer peripheral edge of the resonator-plate-side second bonding pattern 122 is disposed so as to be adjacent to the outer peripheral edge of the second main surface 102 of the crystal resonator plate 10 (external frame part 12). In this embodiment, the resonator-plate-side first bonding pattern 121 is connected to the resonator-plate-side second bonding pattern 122 via an internal wiring 17 formed on the inner wall surface of the external frame part 12. The internal wiring 17 is provided on the inner wall surface along the Z′ axis direction and on the −X direction side, out of the inner wall surfaces of the external frame part 12. That is, the internal wiring 17 is provided on the inner wall surface orthogonally intersecting the inner wall surface on which the internal wiring 12g as described above is provided. Connection bonding patterns 12b and 12c are formed on the first main surface 101 of the external frame part 12, while a connection bonding pattern 12f is formed on the second main surface 102 of the external frame part 12.

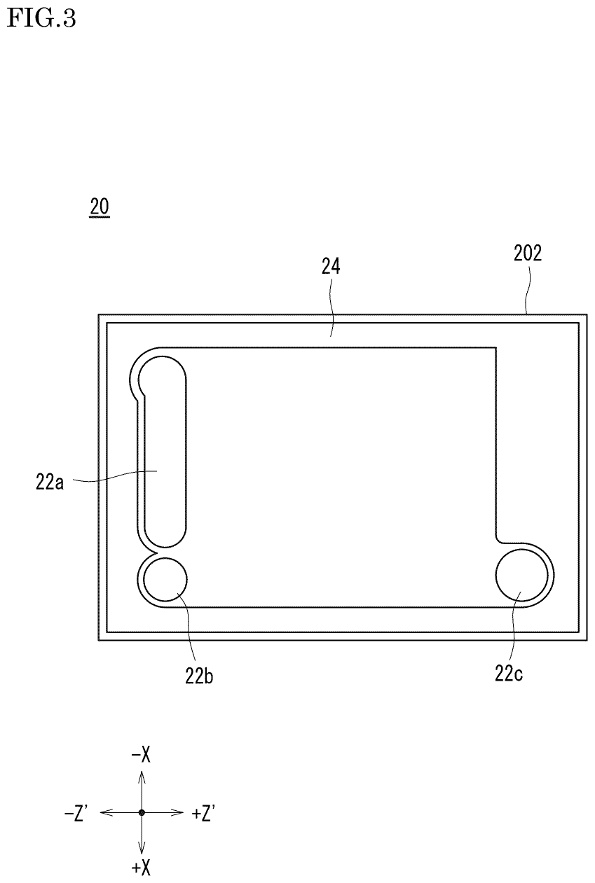

As shown in FIGS. 2 and 3, the first sealing member 20 is a substrate having a rectangular parallelepiped shape that is made of a single AT-cut crystal plate. A second main surface 202 (a surface to be bonded to the crystal resonator plate 10) of the first sealing member 20 is formed as a smooth flat surface (mirror finished). By making the first sealing member 20, which does not have the vibrating part, of the AT-cut crystal plate as in the case of the crystal resonator plate 10, it is possible for the first sealing member 20 to have the same coefficient of thermal expansion as the crystal resonator plate 10. Thus, it is possible to prevent thermal deformation of the crystal oscillator 100. Furthermore, the respective directions of the X axis, the Y axis and the Z′ axis of the first sealing member 20 are the same as those of the crystal resonator plate 10. In this embodiment, it is possible to remarkably shorten the manufacturing process of the first sealing member 20 because of its configuration without any through holes and castellations. Also, since the first sealing member 20 has no water entry pathway into the internal space of the package, it is possible to improve corrosion resistance.

On the second main surface 202 of the first sealing member 20, a sealing-member-side first bonding pattern 24 is formed as a sealing-member-side first sealing part so as to be bonded to the crystal resonator plate 10. The sealing-member-side first bonding pattern 24 is formed so as to have an annular shape in plan view. The outer peripheral edge of the sealing-member-side first bonding pattern 24 is disposed so as to be adjacent to the outer peripheral edge of the second main surface 202 of the first sealing member 20. On the second main surface 202 of the first sealing member 20, connection bonding patterns 22a, 22b and 22c are formed so as to be respectively bonded to the connection bonding patterns 12a, 12b and 12c formed on the first main surface 101 of the external frame part 12 of the crystal resonator plate 10.

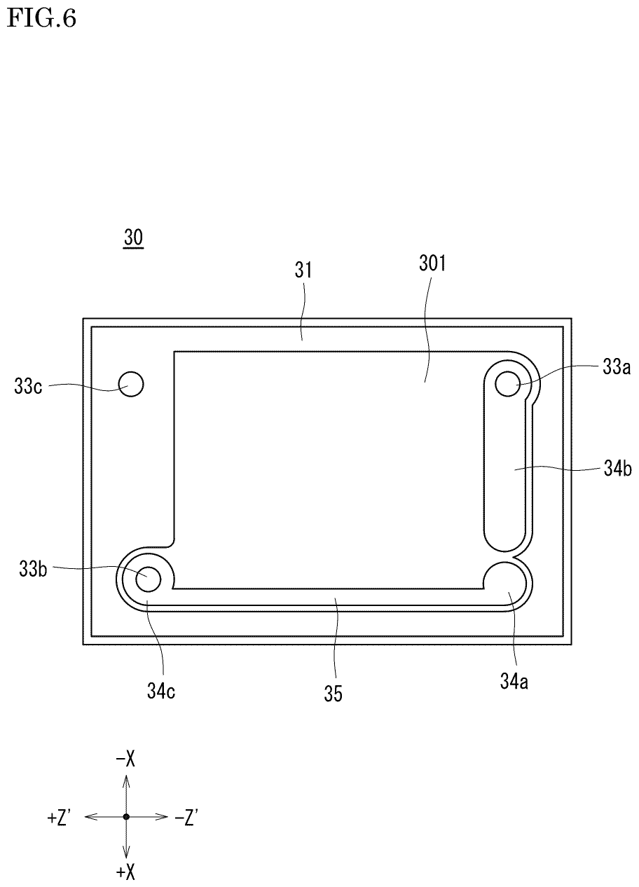

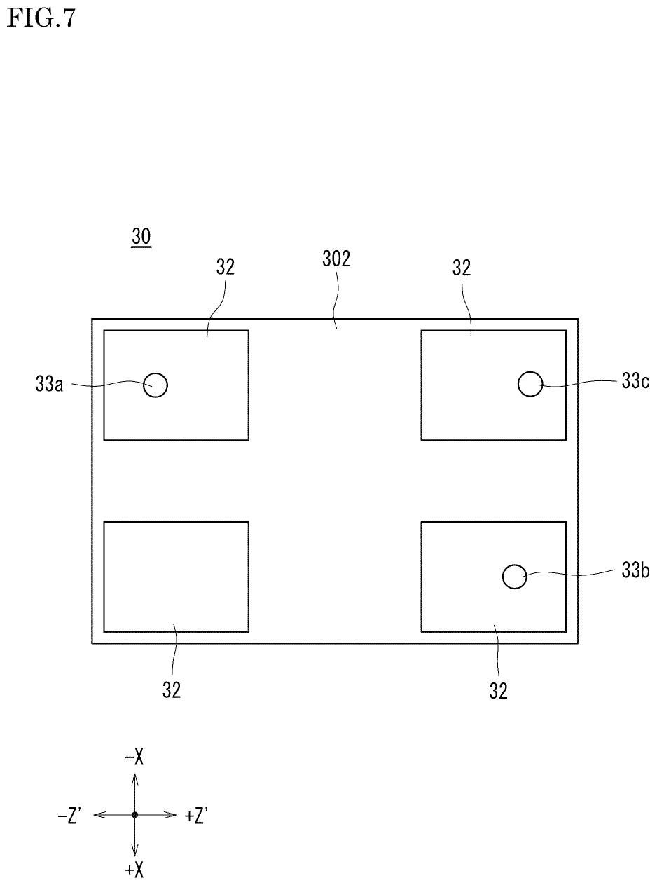

As shown in FIGS. 6 and 7, the second sealing member 30 is a substrate having a rectangular parallelepiped shape that is made of a single AT-cut crystal plate. A first main surface 301 (a surface to be bonded to the crystal resonator plate 10) of the second sealing member 30 is formed as a smooth flat surface (mirror finished). The second sealing member 30 is also preferably made of an AT-cut crystal plate as in the case of the crystal resonator plate 10, and the respective directions of the X axis, the Y axis and the Z′ axis of the second sealing member 30 are preferably the same as those of the crystal resonator plate 10.

On the first main surface 301 of the second sealing member 30, a sealing-member-side second bonding pattern 31 is formed as a sealing-member-side second sealing part so as to be bonded to the crystal resonator plate 10. The sealing-member-side second bonding pattern 31 is formed so as to have an annular shape in plan view. The outer peripheral edge of the sealing-member-side second bonding pattern 31 is disposed so as to be adjacent to the outer peripheral edge of the first main surface 301 of the second sealing member 30. Also, on the first main surface 301 of the second sealing member 30, connection bonding patterns 34a, 34b and 34c are formed so as to be respectively bonded to the connection bonding patterns 12d, 12e and 12f formed on the second main surface 102 of the external frame part 12 of the crystal resonator plate 10. The connection bonding pattern 34a and the connection bonding pattern 34c are connected via a wiring pattern 35 extending in the Z′ axis direction.

On a second main surface 302 (the outer main surface not facing the crystal resonator plate 10) of the second sealing member 30, four external electrode terminals 32 are formed, which are electrically connected to an external circuit board provided outside the crystal resonator 100. The external electrode terminals 32 each have a substantially rectangular shape, and are respectively located on four corners (corner parts) on the second main surface 302 of the second sealing member 30. The external electrode terminals 32 are also disposed so as to be superimposed on the external frame part 12 of the crystal resonator plate 10 in plan view.

As shown in FIGS. 6 and 7, three through holes 33a, 33b and 33c are formed in the second sealing member 30 so as to penetrate between the first main surface 301 and the second main surface 302. The through holes 33a, 33b and 33c are respectively located at the region of the four corners (corner parts) of the second sealing member 30. In the through holes 33a, 33b and 33c, through electrodes are respectively formed along a corresponding inner wall surface of the through holes 33a, 33b and 33c so as to establish conduction between the electrodes formed on the first main surface 301 and the second main surface 302. In this way, the respective electrodes formed on the first main surface 301 (connection bonding patterns) are electrically conducted to the external electrode terminals 32 formed on the second main surface 302 via the through electrodes formed along the inner wall surfaces of the through holes 33a, 33b and 33c. Also, respective central parts of the through holes 33a, 33b and 33c are hollow penetrating parts penetrating between the first main surface 301 and the second main surface 302.

In the crystal resonator 100 including the crystal resonator plate 10, the first sealing member 20 and the second sealing member 30, the crystal resonator plate 10 and the first sealing member 20 are subjected to the diffusion bonding in a state in which the resonator-plate-side first bonding pattern 121 and the sealing-member-side first bonding pattern 24 are superimposed on each other, and the crystal resonator plate 10 and the second sealing member 30 are subjected to the diffusion bonding in a state in which the resonator-plate-side second bonding pattern 122 and the sealing-member-side second bonding pattern 31 are superimposed on each other, thus, the package having the sandwich structure as shown in FIG. 1 is produced. Accordingly, the internal space of the package, i.e. the space to house the vibrating part 11 is hermetically sealed.

In this case, the respective connection bonding patterns as described above are also subjected to the diffusion bonding in a state in which they are each superimposed on the corresponding connection bonding pattern. Such bonding between the connection bonding patterns allows electrical conduction of the first excitation electrode 111, the second excitation electrode 112 and the external electrode terminals 32 and 32 of the crystal resonator 100. More specifically, the first excitation electrode 111 is connected to the external electrode terminal 32 via the first lead-out wiring 113, the internal wiring 12g, and the through electrode of the through hole 33a in this order. The second excitation electrode 112 is connected to the external electrode terminal 32 via the second lead-out wiring 114, the wiring pattern 35 and the through electrode of the through hole 33b in this order.

In the crystal resonator 100, the bonding patterns are each preferably made of a plurality of layers laminated on the crystal plate, specifically, a Ti (titanium) layer and an Au (gold) layer deposited by the vapor deposition or sputtering in this order from the lowermost layer side. Also, the other wirings and electrodes formed on the crystal resonator 100 each preferably have the same configuration as the bonding patterns, which leads to patterning of the bonding patterns, the wirings and the electrodes at the same time.

In the above-described crystal resonator 100, sealing parts (seal paths) 15 and 16 that hermetically seal the vibrating part 11 of the crystal resonator plate 10 are formed so as to have an annular shape in plan view. The seal path 15 is formed by the diffusion bonding (Au—Au bonding) of the resonator-plate-side first bonding pattern 121 and the sealing-member-side first bonding pattern 24 as described above. The outer edge of the seal path 15 has a substantially rectangular shape. The outer peripheral edge of the seal path 15 is disposed so as to be adjacent to the outer peripheral edge of the package. In the same way, the seal path 16 is formed by the diffusion bonding (Au—Au bonding) of the resonator-plate-side second bonding pattern 122 and the sealing-member-side second bonding pattern 31 as described above. The outer edge of the seal path 16 has a substantially rectangular shape, and the outer peripheral edge of the seal path 16 is disposed so as to be adjacent to the outer peripheral edge of the package. The seal paths 15 and 16 are not electrically connected to the electrical conduction paths between the external electrode terminals 32 and 32 and the first and second excitation electrodes 111 and 112. Specifically, the seal path 15 is connected to the seal path 16 via the internal wiring 17, and furthermore the seal path 16 is earth-connected (ground connection using parts of the external electrode terminals 32) via the through electrode of the through hole 33c.

In the crystal resonator 100 having the seal paths 15 and 16 formed by the diffusion bonding as described above, the first sealing member 20 and the crystal resonator plate 10 have a gap of not more than 1.00 μm. The second sealing member 30 and the crystal resonator plate 10 have a gap of not more than 1.00 μm. That is, the thickness of the seal path 15 between the first sealing member 20 and the crystal resonator plate 10 is not more than 1.00 μm, and the thickness of the seal path 16 between the second sealing member 30 and the crystal resonator plate 10 is not more than 1.00 μm (specifically, the thickness in the Au—Au bonding in this embodiment is 0.15 to 1.00 μm). As a comparative example, the conventional metal paste sealing material containing Sn has a thickness of 5 to 20 μm.

In this embodiment, the cutout part 10a is provided by cutting out the substrate between the vibrating part 11 and the external frame part 12 of the crystal resonator plate 10 having the above-described configuration. The electrode (seal path 15) formed on the first main surface 101 of the substrate is electrically connected to the electrode (seal path 16) formed on the second main surface 102 of the substrate via the internal wiring 17 formed on the inner wall surface of the external frame part 12. In the space of the cutout part 10a, first areas A1 represent respective areas sandwiched between the inner wall surfaces of the external frame part 12 and the outer wall surfaces of the vibrating part 11. In the remaining space of the cutout part 10a except the first areas A1, second areas A2 represent respective areas sandwiched between the inner wall surfaces of the external frame part 12 and the outer wall surfaces of the support part 13, and furthermore third areas A3 represent respective areas sandwiched between the inner wall surfaces of the external frame part 12. In this case, the internal wiring 17 is formed on the inner wall surface of the external frame part 12, at a position facing at least one of the second areas A2 and the third areas A3. This positioning will be described referring to FIG. 4.

As shown in FIG. 4, the space of the cutout part 10a is divided into a plurality of areas (in FIG. 4, eight areas) by four straight lines L1 to L4 along the outer peripheral edges (outer wall surfaces) of the rectangular-shaped vibrating part 11 in plan view. The straight lines L1 and L2 are straight lines parallel to each other in the Z′ axis direction. The straight lines L3 and L4 are straight lines parallel to each other in the X axis direction. Each of the first areas A1 is an area sandwiched between the inner wall surface of the external frame part 12 and the outer wall surface of the vibrating part 11. The first areas A1 are provided in four parts respectively making contact with the outer wall surfaces of the vibrating part 11. The first areas A1 are respectively opposed to each other in the X axis direction and in the Z′ axis direction with the vibrating part 11 being interposed therebetween. The first areas A1 are provided at positions other than the spaces of the four corners of the cutout part 10a.

In the remaining space of the cutout part 10a except the first areas A1, the second areas A2 are provided so as to be sandwiched between the inner wall surfaces of the external frame part 12 and the outer wall surfaces of the support part 13. Out of the four corner spaces of the cutout part 10a, the second areas A2 are provided respectively at two of them in the −Z′ direction. In the remaining space of the cutout part 10a except the first areas A1, the third areas A3 are provided so as to be sandwiched between the inner wall surfaces of the external frame part 12. Out of the four corner spaces of the cutout part 10a, the third areas A3 are provided respectively at two of them in the +Z′ direction.

In this embodiment, the internal wiring 17 is formed on the inner wall surface of the external frame part 12, at a position facing one of the third areas A3. More specifically, the internal wiring 17 is formed at a position facing the third area A3 at the corner part of the cutout part 10a in the −X direction and in the +Z′ direction. Out of the inner wall surfaces of the external frame part 12, the internal wiring 17 is formed on the inner wall surface along the Z′ axis direction. The support part 13 and the internal wiring 17 are diagonally positioned in the space of the cutout part 10a.

In this embodiment, it is possible to reduce the size of the crystal resonator plate 10 while maintaining stability of the electrical characteristics. Specifically, since the electrode (seal path 15) formed on the first main surface 101 of the external frame part 12 is connected to the electrode (seal path 16) formed on the second main surface 102 via the internal wiring 17, there is no need to form the through holes or the like in the external frame part 12. Thus, it is possible to reduce the size of the crystal resonator plate 10 while maintaining the effective area of the vibrating part 11. Also, the part of the inner wall surface of the external frame part 12, which faces (makes contact with) the third area A3, has a large width of cutout compared to the adjacent part of the inner wall surface of the external frame part 12, which faces (makes contact with) the first area A1. Thus, it is possible to ensure the space between the opposite wall surfaces. In this way, it is possible to form the internal wiring 17 at a position not facing the vibrating part 11, which prevents the vibrating part 11 from making contact with the internal wiring 17. As a result, it is possible to prevent disconnection and the like.

Furthermore, it is possible to easily and reliably form the internal wiring 17 on the inner wall surface of the external frame part 12. In the photolithography process for forming the internal wiring 17 on the inner wall surface of the external frame part 12, when the internal wiring 17 is formed on the inner wall surface in the area where the distance between the vibrating part 11 and the external frame part 12 is small (for example, in the first area A1), resist may remain on the above area, which leads to difficulty in forming the internal wiring 17. However, in this embodiment, it is possible to reliably remove the resist on the inner wall surface of the external frame part 12 and on the outer wall surface of the vibrating part 11 in the photolithography process for forming the internal wiring 17 on the inner wall surface of the external frame part 12, which leads to reliable forming of the internal wiring 17 on the inner wall surface of the external frame part 12. Therefore, since the electrode (seal path 15) formed on the first main surface 101 of the external frame part 12 can be electrically stably and reliably conducted to the electrode (seal path 16) formed on the second main surface 102, it is possible to prevent degradation of electrical characteristics of the crystal resonator plate 10 and to reduce occurrence of defective products.

The same functions and effects as explained above on the crystal resonator plate 10 can be obtained when using the crystal resonator 100 including the crystal resonator plate 10 as above. Furthermore, since the internal wiring 17 is not exposed to the outer surface of the package of the crystal resonator 100, it is possible to prevent disconnection or scraping of the internal wiring 17 caused by contact or the like during assembly or transport.

In this embodiment, the annular seal path 15 formed on the first main surface 101 of the external frame part 12 of the crystal resonator plate 10 is connected to the annular seal path 16 formed on the second main surface 102 of the external frame part 12 via the internal wiring 17. By adopting this configuration, it is possible to reliably connect the seal paths 15 and 16 to each other via the internal wiring 17. Accordingly, the seal paths 15 and 16 can be reliably earth-connected, which improves shieldability by the seal paths 15 and 16.

In this embodiment, only one support part 13 is provided so as to extend from the corner part of the vibrating part 11 toward the external frame part 12. By adopting this configuration, it is possible to ensure multiple second areas A2 and multiple third areas A3 in the cutout part 10a. Thus, the stability of conduction by the internal wiring 17 can be improved, and furthermore the main vibration of the crystal resonator plate 10 is not likely to be reduced.

Also, the internal wiring 17 is provided on the inner wall surface of the external frame part 12 along the Z′ axis direction of the AT-cut crystal. During the wet etching process for forming the cutout part 10a, an inclined surface often including an acute angle is formed on the inner wall surface of the external frame part 12 along the X axis direction of the AT-cut crystal, which may result in disconnection or the like at the time of forming the internal wiring. However, such a part having an acute angle is not likely to appear on the inner wall surface of the external frame part 12 along the Z′ axis direction of the AT-cut crystal. Therefore, it is possible to easily form the internal wiring 17 while reducing the risk of disconnection or the like. It is preferable that the internal wiring 17 is formed so as to have a certain distance from the end part of the inner wall surface of the external frame part 12 along the Z′ axis direction of the AT-cut crystal.

The above-disclosed embodiment is to be considered in all respects as illustrative and not limiting. The technical scope of the invention is indicated by the appended claims rather than by the foregoing embodiment, and all modifications and changes that come within the meaning and range of equivalency of the claims are intended to be embraced therein.

In the above-described embodiment, the internal wiring 17 is formed at a position facing the third area A3 at the corner part of the cutout part 10a in the −X direction and in the +Z′ direction. However, the present invention is not limited thereto. The internal wiring 17 may be formed at a position facing the third area A3 at the corner part of the cutout part 10a in the +X direction and in the +Z′ direction. Alternatively, the internal wiring 17 may be formed at a position facing the second area A2 at the corner part of the cutout part 10a in the −X direction and in the −Z′ direction.

In the above-described embodiment, only one internal wiring 17 is provided. However, the present invention is not limited thereto. £ A plurality of internal wirings 17 may be provided. For example, the internal wirings 17 may be provided on the inner wall surfaces of the external frame part 12, respectively at positions facing the two third areas A3. Alternatively, one internal wiring 17 may be provided at a position facing the second area A2 and another internal wiring 17 may be provided at a position facing the third area A3, out of the inner wall surfaces of the external frame part 12. As to the inner wall surfaces of the external frame part 12 here, the internal wiring 17 may be formed on the inner wall surface along the Z′ axis direction, or may be formed on the inner wall surface along the X axis direction. Alternatively, the internal wirings 17 may be formed on both the inner wall surface along the X axis direction and the inner wall surface along the Z′ axis direction. When the internal wiring 17 is formed on the inner wall surface along the X axis direction, it is preferable that the internal wiring 17 is formed on a recess having a V shape that is provided in the inner wall surface of the external frame part 12, similarly to the case of the internal wiring 12g.

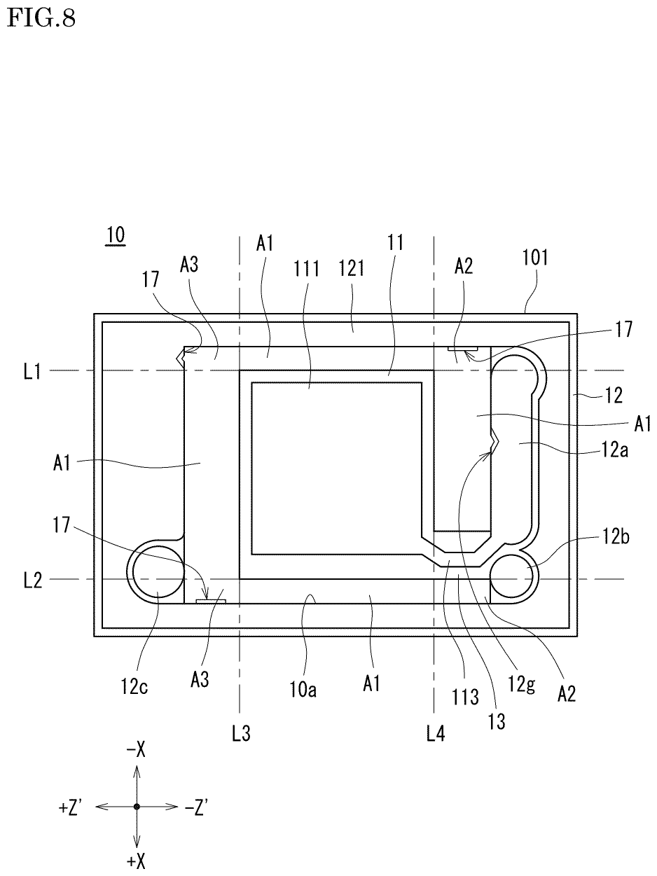

In the example shown in FIG. 8, three internal wirings 17 are provided on the inner wall surfaces of the external frame part 12. More specifically, a first internal wiring 17 is provided on the inner wall surface of the external frame part 12 along the Z′ axis direction and on the −X direction side, at a position facing the second area A2 at the corner part of the cutout part 10a in the −X direction and in the −Z′ direction. Also, a second internal wiring 17 is provided on the inner wall surface of the external frame part 12 along the Z′ axis direction and on the +X direction side, at a position facing the third area A3 at the corner part of the cutout part 10a in the +X direction and in the +Z′ direction. Furthermore, a third internal wiring 17 is provided on the inner wall surface of the external frame part 12 along the X axis direction and on the +Z′ direction side, at a position facing the third area A3 at the corner part of the cutout part 10a in the −X direction and in the +Z′ direction. The third internal wiring 17 is formed on a recess having a V shape that is provided on the +Z′ direction side of the inner wall surface of the external frame part 12.

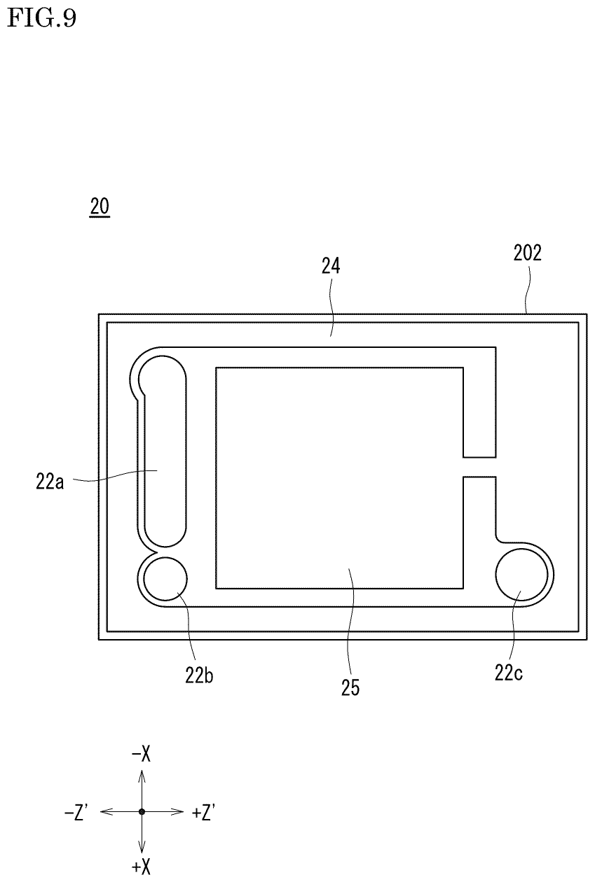

In the above-described embodiment, the electrodes of the annular seal paths 15 and 16, which are formed respectively on the first main surface 101 and the second main surface 102 of the external frame part 12 of the crystal resonator plate 10, are connected to each other via the internal wiring 17. However, the present invention is not limited thereto. Other electrodes may also be connected via the internal wiring 17. For example, the internal wiring 17 may be connected to the first lead-out wiring 113 drawn out from the first excitation electrode 111, or may be connected to the second lead-out wiring 114 drawn out from the second excitation electrode 112. Furthermore, the internal wiring 17 may be connected to the wiring electrode that is earth-connected, as shown in FIG. 9.

In the example shown in FIG. 9, a grounding electrode 25 is formed on the second main surface 202 of the first sealing member 20. The grounding electrode 25 is connected to the seal path 15 on the first main surface 101 of the external frame part 12 of the crystal resonator plate 10, and furthermore is connected to the seal path 16 on the second main surface 102 of the external frame part 12 of the crystal resonator plate 10 via the internal wiring 17. The seal path 16 is connected to the external electrode terminal 32 formed on the second main surface 302 of the second sealing member 30 via the through electrode in the through hole 33c. In this configuration, it is possible to reliably connect the grounding electrode 25 and the external electrode terminal 32 via the internal wiring 17, which improves shieldability by the grounding electrode 25. In this case, since the second main surface 202 of the first sealing member 20 can be effectively used as an installation space of the grounding electrode 25, it is possible to ensure a large size of the grounding electrode 25 and thus to improve shieldability by the grounding electrode 25. Here, the grounding electrode may be provided on the first main surface 201 of the first sealing member 20, or alternatively, the grounding electrodes may be provided on both the first and second main surfaces 201 and 202 of the first sealing member 20.

In the above-described embodiment, the crystal resonator plate 10 has a configuration in which only one support part 13 for connecting the vibrating part 11 to the external frame part 12 is provided and the cutout part 10a is continuously formed so as to surround the outer periphery of the vibrating part 11. However, what is required is to have the cutout part 10a provided between the vibrating part 11 and the external frame part 12, and thus the configuration of the crystal resonator plate 10 may be variously changed. For example, the crystal resonator plate 10 may have a configuration in which two or more support parts 13 are provided so as to connect the vibrating part 11 to the external frame part 12. Also, the support part 13 may extend from a part other than the corner part of the vibrating part 11 toward the external frame part 12.

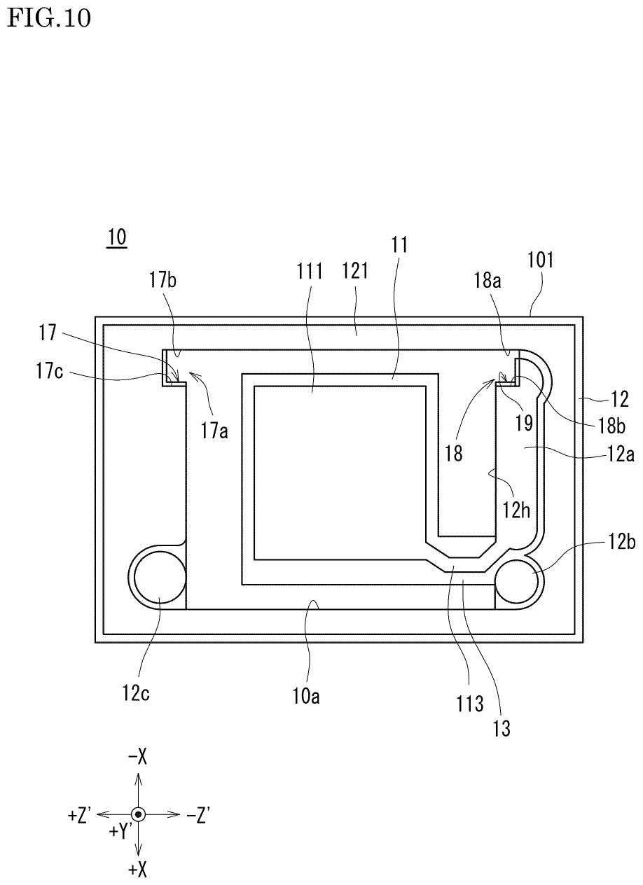

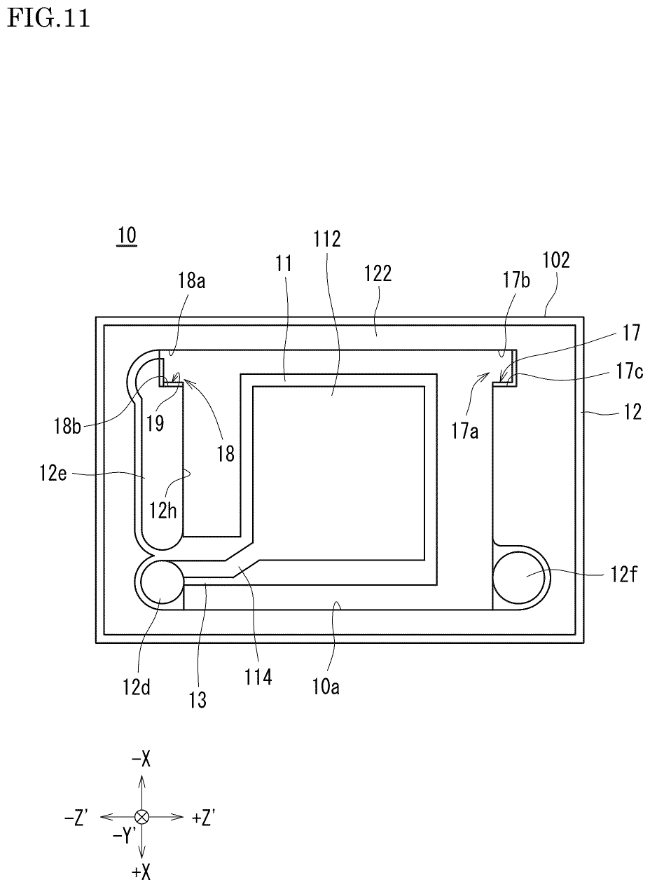

It is also possible to provide the above-described internal wiring 17 for earth-connecting on the region along a short side of the external frame part 12 of the crystal resonator plate 10. For example, as shown in FIGS. 10 and 11, a notch part 17a is formed on the Z′ end surface (i.e. the end surface parallel to the Z′ axis direction) of the inner wall surface 12h of the external frame part 12, on the end part in the +Z′ direction. The internal wiring 17 for earth-connecting is formed on the inner wall surface of the notch part 17a. More specifically, as shown in FIGS. 10 and 11, inner wall surface 12h of the external frame part 12 of the crystal resonator plate 10 is formed annularly so as to have a rectangular shape in plan view. The notch part 17a is formed at a corner part of the inner wall surface 12h in plan view so as to cut into the external frame part 12. The notch part 17a has a substantially rectangular shape in plan view, and is formed in the inner wall surface along the X axis direction and on the +Z′ direction side, out of the inner wall surfaces 12h of the external frame part 12. The notch part 17a is formed so as to cut into the external frame part 12. In other words, the space of the notch part 17a protrudes outside toward the external frame part 12. The notch part 17a is continuously provided to the above-described cutout part 10a of the crystal resonator plate 10. In this way, the internal wiring 17 is formed on the inner wall surface of the external frame part 12, at a position facing one of the third areas A3 (see, for example, FIG. 4).

Here, a second inner wall part 17c (a wall part on the +Z′ direction side and a wall part on the +X direction side) of the notch part 17a is formed so as not to make a straight line with the inner wall surface 12h (the inner wall surface on the +Z′ direction side) of the external frame part 12. Also, the second inner wall part 17c is formed not along the X end surface (i.e. the end surface parallel to the X axis direction) of the inner wall surface 12h of the external frame part 12. Accordingly, there is no corner part protruding in the −Z′ direction and in the +X direction in the second main surface 102 (the surface on the −Y′ direction side) of the inner wall surfaces 12h of the external frame part 12, which prevents forming of gouges by etching due to such a corner part.

The internal wiring 17 is formed on the second inner wall part 17c so as to extend the resonator-plate-side first bonding pattern 121 formed on the first main surface 101 of the external frame part 12 to the second main surface 102. Via the internal wiring 17, the resonator-plate-side first bonding pattern 121 formed on the first main surface 101 of the external frame part 12 is connected to the resonator-plate-side second bonding pattern 122 formed on the second main surface 102 of the external frame part 12. Although it is not shown in the figures, an inclined surface is formed on the second inner wall part 17c as in the embodiment described above. The inclined surface forms an obtuse angle with the second main surface 102 of the external frame part 12, and on this inclined angle, the internal wiring 17 is formed.

In the example shown in FIGS. 10 and 11, in addition to the internal wiring 17 for earth-connecting, a notch part 18 is formed on the Z′ end surface of the inner wall surface 12h of the external frame part 12, on the end part in the −Z′ direction, so that an internal wiring 19 is formed on the inner wall surface of the notch part 18. The notch part 18, whose shape is a substantial rectangle in plan view, has a configuration substantially the same as that of the above-described notch part 17a. The notch part 18 is formed in the inner wall surface along the X axis direction and on the −Z′ direction side, out of the inner wall surfaces 12h of the external frame part 12. The internal wiring 19 is formed on the inner wall surface of the external frame part 12, at a position facing the second area A2 (see, for example, FIG. 4). The notch part 18 is formed so as to cut into the external frame part 12, and is continuously provided to the cutout part 10a of the crystal resonator plate 10. The connection bonding pattern 12a is connected to the connection bonding pattern 12e formed on the second main surface 102 of the external frame part 12 via the internal wiring 19 formed on the notch part 18 in the inner wall surface 12h of the external frame part 12.

In the example shown in FIGS. 10 and 11, it is possible to prevent disconnection of the internal wirings 17 and 19 by forming each inner wall surface of the notch parts 17a and 18 as the inclined surface. Also, since the notch parts 17a and 18b are formed so as to cut into the external frame part 12, it is possible to ensure the effective area of the vibrating part 11, which leads to the crystal resonator plate 10 having a reduced size and stable electrical characteristics. In this example, the notch parts 17a and 18 each have the substantially rectangular shape. However, the present invention is not limited thereto. The shape of the notch parts 17a and 18 may be a V shape, a trapezoidal shape, an arc shape, or an elliptical arc shape.

In the above-described embodiment, the AT-cut crystal resonator plate is used as the crystal resonator plate 10. However, other crystal resonator plates (for example, an SC-cut crystal resonator plate and a Z-cut quartz plate) may be used.

In the above-described embodiment, the number of the external electrode terminals 32 on the second main surface 302 of the second sealing member 30 is four. However, the present invention is not limited thereto. The number of the external electrode terminals 32 may be, for example, two, six, or eight. Also, the present invention is applied to the crystal resonator 100. However, the present invention is not limited thereto. The present invention may be applied, for example, to a piezoelectric oscillator such as a crystal oscillator. In the case of the crystal oscillator, it is possible to connect the internal wiring 17 to a wiring electrode connected to the IC mounted on the crystal resonator.

In the above-described embodiment, the first sealing member 20 and the second sealing member 30 are each made of a crystal plate. However, the present invention is not limited thereto. The first sealing member 20 and the second sealing member 30 may be made of, for example, glass or resin.

In the above-described embodiment, the present invention is applied to the three-layered piezoelectric resonator device in which the crystal resonator plate is sandwiched between the first sealing member and the second sealing member. However, the present invention is not limited thereto. The present invention may be applied to a piezoelectric resonator device having a structure where the crystal resonator plate is installed in a base made of ceramic or the like.

This application claims priority based on Patent Application No. 2023-032554 filed in Japan on Mar. 3, 2023. The entire contents thereof are hereby incorporated in this application by reference.

### DESCRIPTION OF THE REFERENCE NUMERALS

10 Crystal resonator plate
10a Cutout part
11 Vibrating part
12 External frame part
13 Support part
17 Internal wiring
100 Crystal resonator
111 First excitation electrode
112 Second excitation electrode
A1 First area
A2 Second area
A3 Third area

1. A piezoelectric resonator plate having a rectangular shape, comprising:
a first excitation electrode formed on a first main surface of a substrate; and a second excitation electrode formed on a second main surface of the substrate, the second excitation electrode making a pair with the first excitation electrode, wherein
the piezoelectric resonator plate further includes: a vibrating part having a rectangular shape; an external frame part surrounding an outer periphery of the vibrating part; at least one support part connecting a part of the vibrating part to a part of the external frame part; and a cutout part formed by cutting out the substrate such that the cutout part is interposed between the vibrating part and the external frame part,
an electrode formed on the first main surface of the substrate is electrically connected to an electrode formed on the second main surface of the substrate via an internal wiring formed on an inner wall surface of the external frame part, and
in a space of the cutout part, when a first area represents an area sandwiched between the inner wall surface of the external frame part and an outer wall surface of the vibrating part, and when, in a remaining space of the cutout part except the first area, a second area represents an area sandwiched between the inner wall surface of the external frame part and an outer wall surface of the at least one support part and furthermore a third area represents an area sandwiched between two parts of the inner wall surface of the external frame part, the internal wiring is formed on the inner wall surface of the external frame part, at a position facing at least one of the second area and the third area.

2. The piezoelectric resonator plate according to claim 1, wherein
the inner wall surface of the external frame part is formed annularly so as to have a rectangular shape in plan view,
a notch part is formed at a corner part of the inner wall surface in plan view so as to cut into the external frame part, and
the internal wiring is formed on an inner wall surface of the notch part.

3. A piezoelectric resonator device comprising the piezoelectric resonator plate according to claim 1, wherein
the piezoelectric resonator device further includes: a first sealing member covering the first excitation electrode of the piezoelectric resonator plate; and a second sealing member covering the second excitation electrode of the piezoelectric resonator plate,
an internal space is formed by bonding the first sealing member to the piezoelectric resonator plate and furthermore by bonding the second sealing member to the piezoelectric resonator plate, and
the internal space hermetically seals the vibrating part including the first excitation electrode and the second excitation electrode of the piezoelectric resonator plate.

4. The piezoelectric resonator device according to claim 3, wherein
a grounding electrode formed on one main surface of both main surfaces of the first sealing member is electrically connected to an external electrode terminal formed on a main surface, which does not face the internal space, of the second sealing member via the internal wiring.

5. The piezoelectric resonator device according to claim 3, wherein
annular-shaped sealing parts are respectively provided between the first sealing member and the piezoelectric resonator plate, and between the second sealing member and the piezoelectric resonator plate, so as to hermetically seal the vibrating part of the piezoelectric resonator plate, and
the respective annular-shaped sealing parts are electrically connected to the internal wiring.

6. The piezoelectric resonator device according to claim 3, wherein
the piezoelectric resonator plate includes only one support part as the at least one support part, and the one support part extends from a corner part of the vibrating part toward the external frame part.

7. The piezoelectric resonator device according to claim 3, wherein
the piezoelectric resonator plate is made of an AT-cut crystal resonator plate, and
the internal wiring is formed on the inner wall surface of the external frame part along a Z′ axis direction of the AT-cut crystal plate.
